(19) United States
(12) Patent Application Publication
(10) Pub. No.: US 2013/0271115 A1
(43) Pub. Date: Oct. 17, 2013

(54) POWER SUPPLY EFFICIENCY MEASUREMENT DEVICE

(71) Applicants: HONG FU JIN PRECISION INDUSTRY (SHENZHEN) CO., LT, Shenzhen (CN); HON HAI PRECISION INDUSTRY CO., LTD., New Taipei (TW)

(72) Inventor: HUI LI, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/674,956

(22) Filed: Nov. 13, 2012

(30) Foreign Application Priority Data
Apr. 13, 2012 (CN) 201210108052.1

(51) Int. Cl. G01R 19/00

(52) U.S. Cl. 324/114

(57) ABSTRACT

A power supply efficiency measurement device includes a power meter and an adapter. The power meter includes an ammeter and a voltmeter. The adapter includes a live line connector, a neutral line connector, and two voltage test connectors. The live line connector electrically connects a load with a live line of a power supply, the neutral line connector electrically connects the load with a neutral line of the power supply, and the two voltage test connectors are electrically connected to the live line connector and the neutral line connector respectively. The ammeter is electrically connected between the live line connector and the power supply by the live line, and the voltmeter is electrically connected to both the two voltage test connectors.

### BACKGROUND

1. Technical Field

The present disclosure relates to measurement of electrical parameters, and particularly to a power supply efficiency measurement device.

2. Description of Related Art

Generally, efficiency measurement for a power supply includes these operations: the power supply is utilized to provide power to a load with a rated power; the value of power obtained from the power supply by the load is measured by a power meter; and a ratio of the value of the rated power of the load to the value of the power obtained from the power supply by the load is determined and recorded as the efficiency of the power supply.

Referring to FIG. 4, according to a typical power efficiency measurement method, when efficiency of a power supply 10a is measured, a power meter 20a is electrically connected between the power supply 10a and a load 30a with rated power.

According to ordinary skill, the power supply 10a includes a live line La, a neutral line Na, and a ground line Ga. The live line La, the neutral line Na, and the ground line Ga are all electrically connected to the load 30a via the power meter 20a, and the power supply 10a inputs a power supply voltage to the load 30a via the live line La. The power meter 20a includes an ammeter 21a and a voltmeter 22a. The ammeter 21a is electrically connected between the power supply 10a and the load 30a by the live line La, and measures a value of current output by the power supply 10a. The voltmeter 22a is electrically connected between the live line La and the neutral line Na, and measures a value of a voltage output by the power supply 10a. The power meter 20a determines a value of power output by the power supply 10a according to the measured values. The value of the power output by the power supply 10a is considered as being an equivalent of a value of power obtained from the power supply 10a by the load 30a. Thus, a ratio of the value of the rated power of the load 30a to the value of the power output by the power supply 10a is determined and recorded as the efficiency of the power supply 10a.

However, the above-described method may be unable to achieve a precise result because of the following reason. Generally, the load 30a is a household appliance and includes only one plug 31a for electrical connections. According to the art, shapes of the plug 31a, the live line La, and the neutral line Na are usually unfit for being structurally connected to the power meter 20a. Therefore, the power meter 20a needs to be structurally connected to the power supply 10a to form electrical connections and measure the current and voltage output by the power supply 10a. On this condition, the ammeter 21a, the live line La, and the neutral line Na may consume a part of the voltage output by the power supply 10a, and therefore a voltage received by the load 30a may be lower than the voltage output by the power supply 10a. Thus, a value of power obtained from the power supply 10a by the load 30a may be less than the value of the power output by the power supply 10a. If the value of the power output by the power supply 10a is used to determine the value of the efficiency of the power supply 10a according to the above-described method, the determined value of the efficiency of the power supply 10a may be less than a real value of the efficiency of the power supply 10a.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is a circuit diagram of a power supply efficiency measurement device, according to an exemplary embodiment.

FIG. 2 is a schematic view of an adapter of the power supply efficiency measurement device shown in FIG. 1.

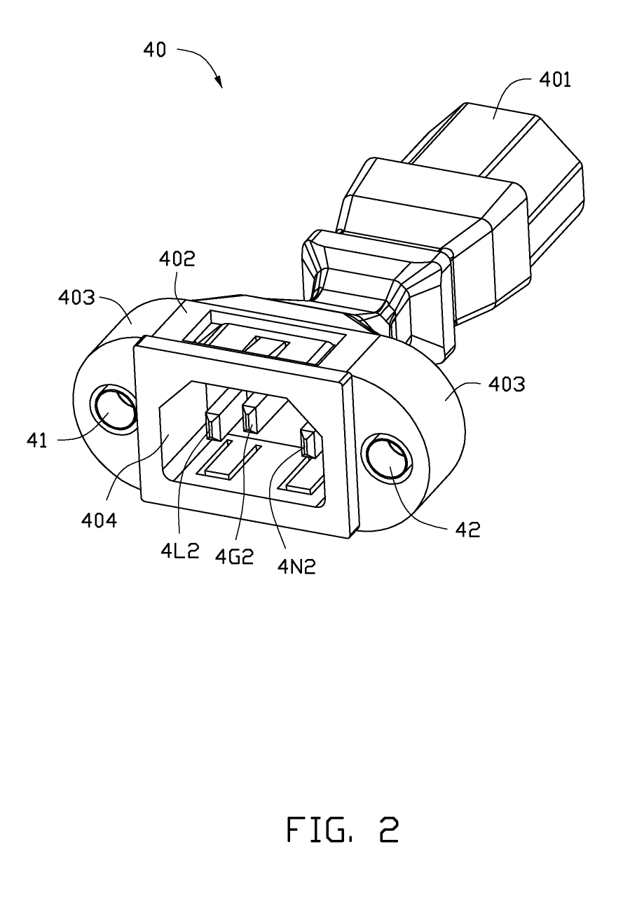

FIG. 3 is similar to FIG. 2, but shown from another direction.

FIG. 4 is a circuit diagram of efficiency measurement of a power supply, according to related art.

### DETAILED DESCRIPTION

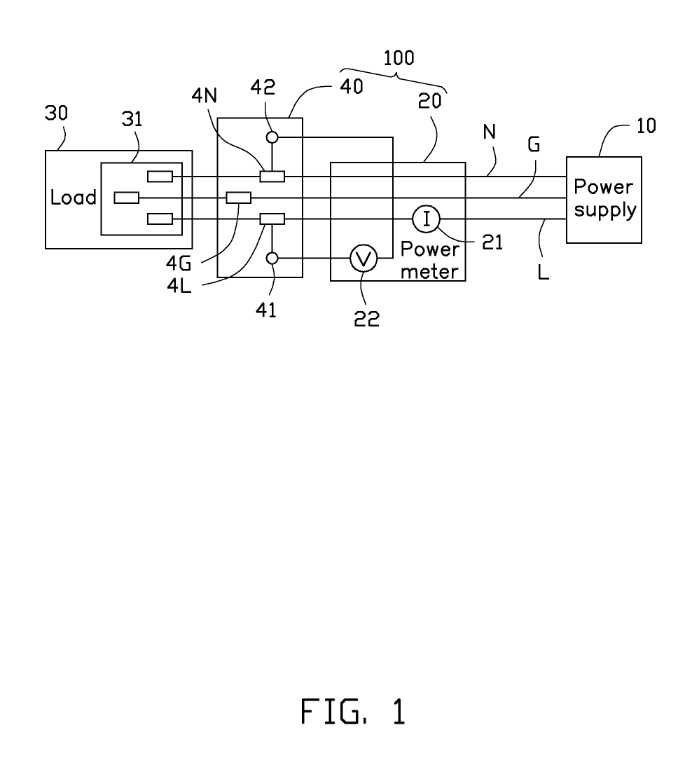

FIG. 1 is a circuit diagram of a power supply efficiency measurement device 100, according to an exemplary embodiment. The power supply efficiency measurement device 100 can cooperate with a load 30, such as a household appliance having a rated power, to measure efficiency of power supply devices. This embodiment illustrates how to use the power supply efficiency measurement device 100 and the load 30 to measure an efficiency of a power supply 10. In this embodiment, the power supply 10 is an alternating current (AC) power supply. The power supply efficiency measurement device 100 can measure a value of power obtained from the power supply device 10 by the load 30, and a ratio of the value of the rated power of the load 30 to the value of the power obtained from the power supply 10 by the load 30 is determined and recorded as the efficiency of the power supply 10.

The power supply efficiency measurement device 100 includes a power meter 20 and an adapter 40. The power meter 20 includes an ammeter 21 and a voltmeter 22. The adapter 40 includes two voltage test connectors 41 and 42, a live line connector 4L, a neutral line connector 4N, and a ground line connector 4G. Since the power supply 10 is an AC power supply, according to ordinary skill, the power supply 10 includes a live line L, a neutral line N, and a ground line G. In this embodiment, the live line L, the neutral line N, and the ground line G are electrically connected to the live line connector 4L, the neutral line connector 4N, and the ground line connector 4G, respectively.

In this embodiment, the load 30 is a common household appliance. According to ordinary skill, the load 30 includes a plug 31, and the plug 31 includes three pins (not labeled). The three pins are respectively configured to be electrically connected to the live line L, the neutral line N, and the ground line G of the power supply 10, and thus can be respectively named as “live line plug pin”, “neutral line plug pin”, and “ground line plug pin”. The plug 31 can be electrically connected to the live line L, the neutral line N, and the ground line G via the live line connector 4L, the neutral line connector 4N, and the ground line connector 4G correspondingly, such that the load 30 can obtain power from the power supply 10.

The ammeter 21 is electrically connected between the power supply 10 and the live line connector 4L by the live line L to measure current output by the power supply 10. The two voltage test connectors 41 and 42 are electrically connected to the live line connector 4L and the neutral line connector 4N respectively, and the voltmeter 22 is electrically connected between the two voltage test connectors 41 and 42 to measure a value of a voltage between the live line L and the neutral line N. The voltage measured by the voltmeter 22 is considered as being an equivalent of a voltage received from the power supply 10 by the load 30, and is used to determine a value of power obtained from the power supply 10 by the load 30.

Generally, shapes of most three-pin plugs are unfit for being structurally connected to the voltmeter 22. Therefore, the adapter 40 is configured for enabling the electrical connection between the plug 31 and the voltmeter 22. A structure of the adapter 40 is detailed as follows.

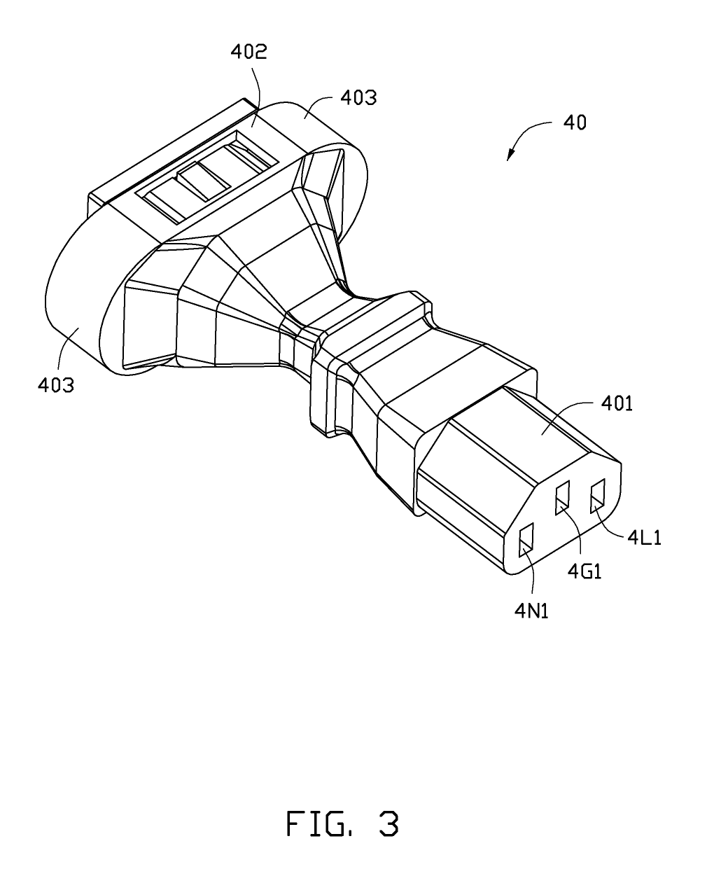

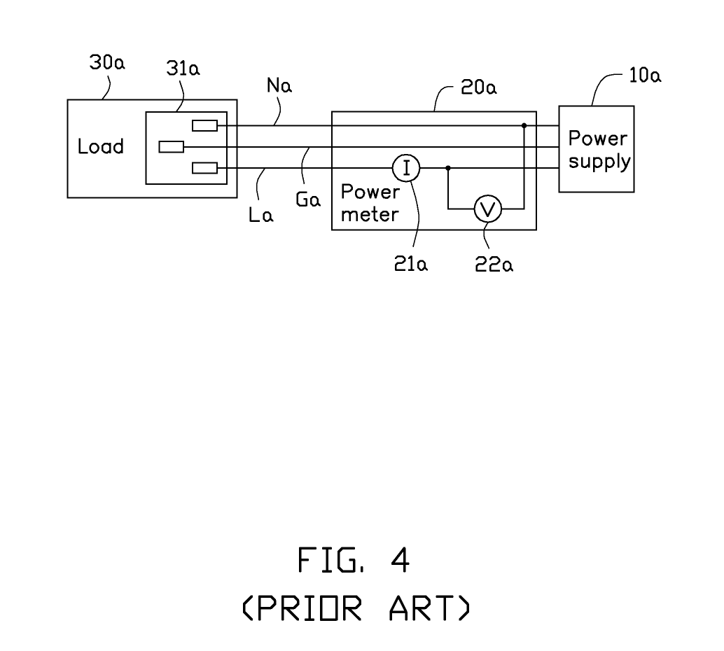

Referring to FIGS. 3 and 4, the adapter 40 includes a load connection portion 401, a power connection portion 402, and two voltage test connection portion 403. The load connection portion 401, the power connection portion 402, and the two voltage test connection portions 403 are all blocks formed by insulating material, such as plastic or rubber. The load connection portion 401 and the power connection portion 402 are structurally connected together, and the two voltage test connection portions 403 protrudes from two opposite sides of the power connection portion 402, respectively.

The live line connector 4L includes a live line jack hole 4L1 and a live line connection pin 4L2. The neutral line connector 4N includes a neutral line jack hole 4N1 and a neutral line connection pin 4N2. The ground line connector 4G includes a ground line jack hole 4G1 and a ground line connection pin 4G2. The live line jack hole 4L1, the neutral line jack hole 4N1, and the ground line jack hole 4G1 are all defined in one end of the load connection portion 401. Shapes, sizes, and positions of the live line jack hole 4L1, the neutral line jack hole 4N1, and the ground line jack hole 4G1 correspond to that of the live line plug pin, the neutral line plug pin, and the ground line plug pin of the plug 31, respectively. Thus, the plug 31 can be structurally connected to the load connection portion 401, with the live line plug pin, the neutral line plug pin, and the ground line plug pin inserted in the live line jack hole 4L1, the neutral line jack hole 4N1, and the ground line jack hole 4G1, correspondingly.

The power connection portion 402 defines a recess 404 therein. Each of the live line connection pin 4L2, the neutral line connection pin 4N2, and the ground line connection pin 4G2 has a middle portion fixed within the power connection portion 402, one end extending from a bottom of the recess 404 and received in the recess 404, and another end received in the load connection portion 401. In this embodiment, the ends of the live line connection pin 4L2, the neutral line connection pin 4N2, and the ground line connection pin 4G2 received in the load connection portion 401 extend into the live line jack hole 4L1, the neutral line jack hole 4N1, and the grounding jack hole 4G1, correspondingly. When the plug 31 is structurally connected to the load connection portion 401, as detailed above, the live line plug pin, the neutral line plug pin, and the ground line plug pin of the plug 31 are inserted in the live line jack hole 4L1, the neutral line jack hole 4N1, and the grounding jack hole 4G1 respectively, and can contact the live line connection pin 4L2, the neutral line connection pin 4N2, and the ground line connection pin 4G2 respectively (i.e., form electrical connections correspondingly). In this way, the load 30 can be electrically connected to other electrical appliances, such as the power supply 10, via the live line connection pin 4L2, the neutral line connection pin 4N2, and the ground line connection pin 4G2.

In this embodiment, the two voltage test connectors 41 and 42 are loops made of conductive material, such as metal. The two voltage test connectors 41 and 42 are respectively mounted on the two voltage test connection portions 403, and are respectively electrically connected to the live line connection pin 4L2 and the neutral line connection pin 4N2 by conventional means, such as wires (not shown) received inside the two voltage test connection portions 403 and the power connection portion 402.

In use, the adapter 40 is electrically connected to the power supply 10 by conventional means, such as jack holes (not shown) of the power supply 10. The live line connector 4L2 is electrically connected to the live line L via the ammeter 21, and the neutral line connector 4N2 and the ground line connector 4G2 are electrically connected to the neutral line N and the ground line G, respectively. The plug 31 is structurally connected to the load connection portion 401 and is electrically connected to the adapter 40 according to the above-described method. Thus, the power supply 10 can supply power to the load 30.

When the load 30 works, the ammeter 21 measures a value of current received by the load 30. The voltmeter 22 is electrically connected to the two voltage test connectors 41 and 42 to measure a value of a voltage two voltage test connectors 41 and 42. Because the two voltage test connectors 41 and 42 are loops and are respectively mounted on the two voltage test connection portions 403 protruding from the power connection portion 402, it is easy to insert two typical connection pins (not shown) of the voltmeter 22 into the two voltage test connectors 41 and 42. In this way, the two connection pins can easily contact the two voltage test connectors 41 and 42 respectively (i.e., form electrical connections with the two voltage test connectors 41 and 42), and the voltmeter 22 can measure a value of the voltage between the two voltage test connectors 41 and 42, without disassembly of components. The value of the voltage between the two voltage test connectors 41 and 42 is considered as being an equivalent of a value of a voltage received by the load 30. Thus, the power meter 20 determines a value of power received from the power supply 10 by the load 30 according to the measured values of the current and the voltage received by the load 30. A ratio of the value of the rated power of the load 30 to the value of the power received from the power supply 10 by the load 30 is determined and recorded as the efficiency of the power supply 10.

Furthermore, according to the art, each of the live line L, the neutral line N, and the ammeter 21 may cause voltage consumption. The two voltage connectors 41 and 42 are electrically connected to the load 30 via only the live line connector 4L1 and the neutral line connector 4N1, and do not need to be electrically connected to the load 30 via any of the live line L, the neutral line N, and the ammeter 21. Therefore, it is readily appreciated that the voltage between the two voltage test connectors 41 and 42 is more similar to a real voltage received by the load 30 than the voltage output by the power supply 10. Compared with typical methods (e.g., as detailed in the Description of Related Art), the power supply efficiency measurement device 100 measures the voltage received by the load 30 more precisely, and therefore more precise values of power received by the power supply 10 and efficiency of the power supply 10 can be obtained.

In other embodiments, the power supply efficiency measurement device 100 can cooperate with a load using direct current (DC) to measure power efficiency of a DC power supply. A method for using such an embodiment is similar to the above-described method, except that the ground line G, the ground line connector 4G, and the ground line plug pin of the plug 31 are all omitted.

In other embodiments, the recess 404 can be omitted, and the live line connection pin 4L2, the neutral line connection pin 4N2, and the ground line connection pin 4G2 can protrude from a distal end of the power connection portion 402. Shapes, sizes, and positions of the live line connection pin 4L2, the neutral line connection pin 4N2, and the ground line connection pin 4G2 can be similar to that of the live line plug pin, the neutral line plug pin, and the ground line plug pin of the plug 31, respectively. In this way, the adapter 40 can also serve as a common plug, such as the plug 31.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A power supply efficiency measurement device, comprising:
a power meter including an ammeter and a voltmeter; and
an adapter including a live line connector, a neutral line connector, and two voltage test connectors; the live line connector configured to electrically connect a load with a live line of a power supply, the neutral line connector configured to electrically connect the load with a neutral line of the power supply, and the two voltage test connectors electrically connected to the live line connector and the neutral line connector respectively; the ammeter electrically connected between the live line connector and the power supply by the live line, and the voltmeter electrically connected to both the two voltage test connectors;
wherein when the power supply supplies power to the load, the ammeter measures a value of current received by the load, the voltmeter measures a value of a voltage between the two voltage test connectors, and the power meter uses the value of a voltage between the two voltage test connectors as a value of a voltage received by the load to determines values of power received by the load and efficiency of the power supply.

2. The power supply efficiency measurement device of claim 1, wherein a ratio of a value of rated power of the load to the value of power received by the load is recorded as the efficiency value of the power supply.

3. The power supply efficiency measurement device of claim 1, wherein the adapter further includes a load connection portion and a power connection portion, both the load connection portion and the power connection portion are blocks made of insulating material, and the load connection portion and the power connection portion are connected together.

4. The power supply efficiency measurement device of claim 4, wherein the adapter further includes two voltage test connection portions, the two voltage test connection portions are blocks made of insulating material and protrude from two opposite sides of the load connection portion respectively, and the two voltage test connectors are mounted on the two voltage test connection portions respectively.

5. The power supply efficiency measurement device of claim 5, wherein the two voltage test connectors are loops made of conductive material.

6. The power supply efficiency measurement device of claim 3, wherein the live line connector includes a live line jack hole and a live line connection pin, and the neutral line connector includes a neutral line jack hole and a neutral line connection pin; both the live line jack hole and the neutral line jack hole are defined in the load connection portion to insert a plug of the load; and the live line connection pin and the neutral line connection pin extends into the live line jack hole and the neutral line jack hole respectively.

7. The power supply efficiency measurement device of claim 6, wherein each of the live line connection pin and the neutral line connection pin has a middle portion received in the power connection portion and an end extending from the power connection portion.

8. The power supply efficiency measurement device of claim 7, wherein the power connection portion defines a recess, and each of the live line connection pin and the neutral line connection pin has an end extending from a bottom of the recess and received in the recess.

9. The power supply efficiency measurement device of claim 1, wherein the adapter further includes a ground line connector configured to electrically connect the load to a ground line of the power supply.
